(19) United States
(12) Patent Application Publication
(10) Pub. No.: US 2013/0016289 A1
(43) Pub. Date: Jan. 17, 2013

(54) TELEVISION AND ELECTRONIC APPARATUS

(71) Applicants: Shinya HAYASHIYAMA, Tachikawa-shi (JP); Noboru NISHIDA, Ome-shi (JP); Makoto TANAKA, Ome-shi (JP)

(72) Inventors: Shinya HAYASHIYAMA, Tachikawa-shi (JP); Noboru NISHIDA, Ome-shi (JP); Makoto TANAKA, Ome-shi (JP)

(73) Assignee: KABUSHIKI KAISHA TOSHIBA, Tokyo (JP)

(21) Appl. No.: 13/435,389

(22) Filed: Mar. 30, 2012

(30) Foreign Application Priority Data
Jul. 14, 2011 (JP) 2011-156006

(51) Int. Cl. H04N 5/655; H05K 7/00

(52) U.S. Cl. 348/836; 361/752; 348/E05.132

(57) ABSTRACT

According to one embodiment, an electronic apparatus includes a housing, a circuit board, a component, and a reinforcing portion. The circuit board is in the housing and includes a first surface and a second surface opposite to the first surface. The component is on the first surface of the circuit board and includes a corner. The reinforcing portion is on the second surface of the circuit board and corresponds to the corner of the component.

### CROSS-REFERENCE TO RELATED APPLICATIONS

This application is based upon and claims the benefit of priority from prior Japanese Patent Application No. 2011-156006, filed Jul. 14, 2011; the entire contents of which are incorporated herein by reference.

### FIELD

Embodiments described herein relate generally to televisions and electronic apparatuses.

### BACKGROUND

Some electronic apparatuses include a reinforcing plate attached to a circuit board.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view of a television according to a first embodiment;

FIG. 2 is an exemplary back view of the internal structure of the television shown in FIG. 1;

FIG. 3 is an exemplary plan view of a circuit board shown in FIG. 2;

FIG. 4 is an exemplary plan view of reinforcing portions shown in FIG. 3;

FIG. 5 is an exemplary enlarged perspective view of one of the reinforcing portions shown in FIG. 4;

FIG. 6 is an exemplary enlarged plan view of one of the reinforcing portions shown in FIG. 4;

FIG. 7 is an exemplary view of an example of a process of mounting the reinforcing portions shown in FIG. 4;

FIG. 8 is an exemplary diagram illustrating the relation between time and stress when an impacting force is applied to a circuit board with low rigidity;

FIG. 9 is an exemplary diagram illustrating the relation between time and stress when an impacting force is applied to a circuit board with high rigidity;

FIG. 10 is an exemplary plan view of a first modification of the reinforcing portion shown in FIG. 6;

FIG. 11 is an exemplary plan view of a second modification of the reinforcing portion shown in FIG. 6;

FIG. 12 is an exemplary plan view of a reinforcing portion according to a second embodiment;

FIG. 13 is an exemplary plan view of a reinforcing portion according to a third embodiment;

FIG. 14 is an exemplary plan view of a reinforcing portion according to a fourth embodiment;

FIG. 15 is an exemplary plan view of a reinforcing portion according to a fifth embodiment;

FIG. 16 is an exemplary plan view of a reinforcing portion according to a sixth embodiment;

FIG. 17 is an exemplary cross-sectional view of a reinforcing portion according to a seventh embodiment;

FIG. 18 is an exemplary plan view of a reinforcing portion according to an eighth embodiment;

FIG. 19 is an exemplary plan view of a reinforcing portion according to a ninth embodiment;

FIG. 20 is an exemplary cross-sectional view of a reinforcing portion according to a tenth embodiment;

FIG. 21 is an exemplary plan view of a reinforcing portion according to an eleventh embodiment; and

FIG. 22 is an exemplary perspective view of a reinforcing portion according to a twelfth embodiment.

### DETAILED DESCRIPTION

Various embodiments will be described hereinafter with reference to the accompanying drawings.

In general, according to one embodiment, an electronic apparatus comprises a housing, a circuit board, a component, and a reinforcing portion. The circuit board is in the housing and comprises a first surface and a second surface opposite to the first surface. The component is on the first surface of the circuit board and comprises a corner. The reinforcing portion is on the second surface of the circuit board and corresponds to the corner of the component.

Hereinafter, exemplary embodiments will be described with reference to the drawings.

### First Embodiment

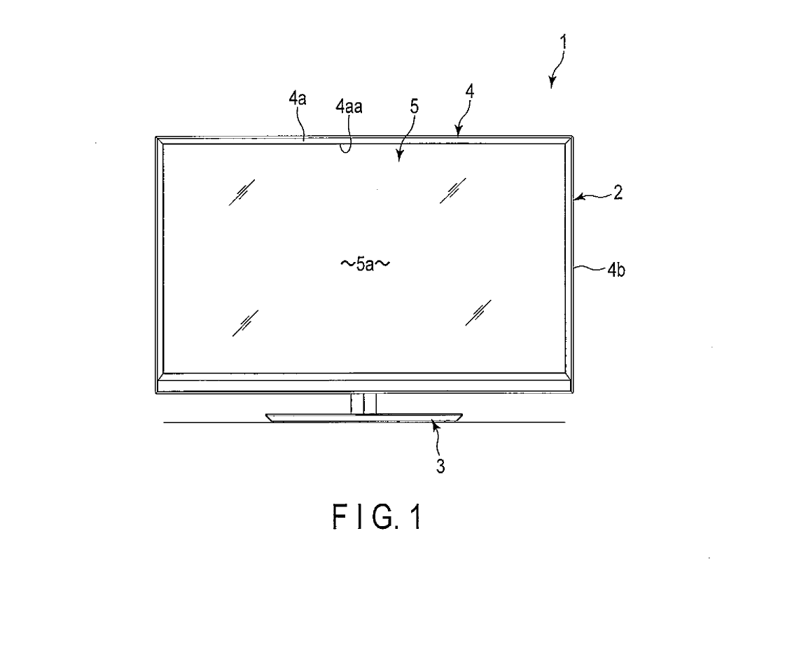

FIGS. 1 to 9 show a television 1 according to a first embodiment. The television 1 is an example of an “electronic apparatus”. As shown in FIG. 1, the television 1 includes a display unit 2 and a stand 3 supporting the display unit 2. The display unit 2 includes a housing 4 and a display device 5 provided in the housing 4. The housing 4 includes a front wall 4a, a rear wall, and a circumferential wall 4b provided between the front wall 4a and the rear wall. The display device 5 includes a display screen 5a on which images are displayed. The front wall 4a of the housing 4 has an opening portion 4aa through which the display screen 5a is exposed.

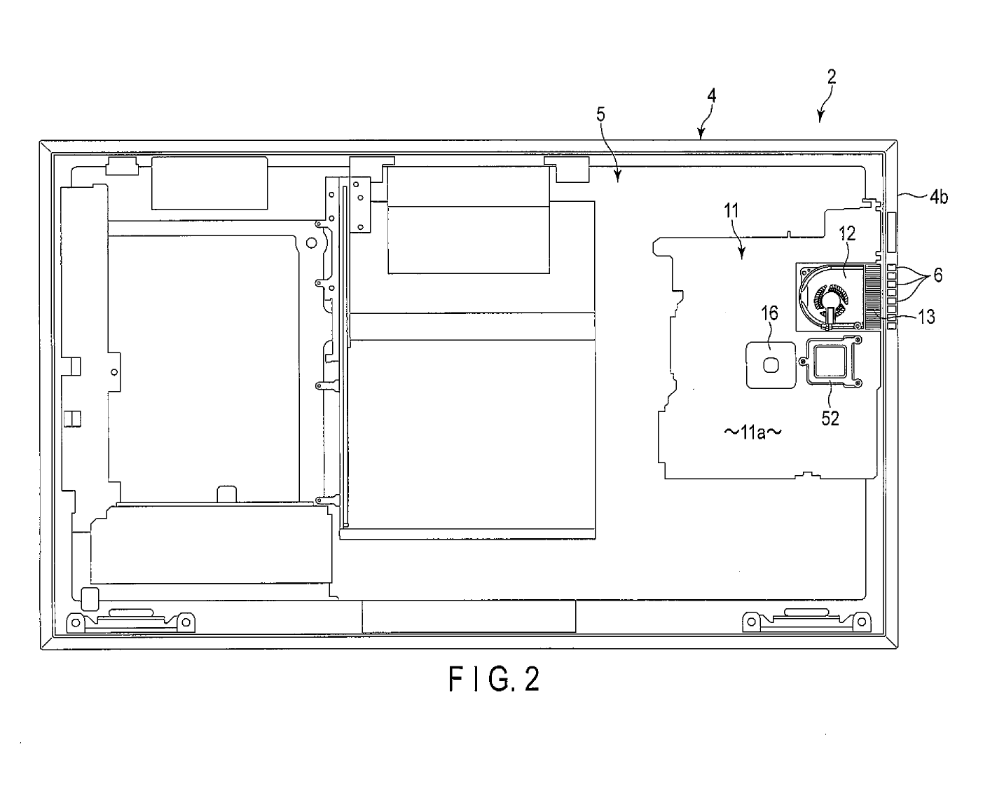

FIG. 2 is a diagram schematically illustrating an example of the internal structure of the housing 4. As shown in FIG. 2, at least either the circumferential walls 4b (i.e., side wall) or the rear wall of the housing 4 includes at least one exhaust hole 6 (i.e., opening portion). The housing 4 has a circuit board 11, a fan 12, a heat sink 13, and a thermally-conductive member 14 provided therein. The circuit board 11 is electrically connected to, for example, the display device 5.

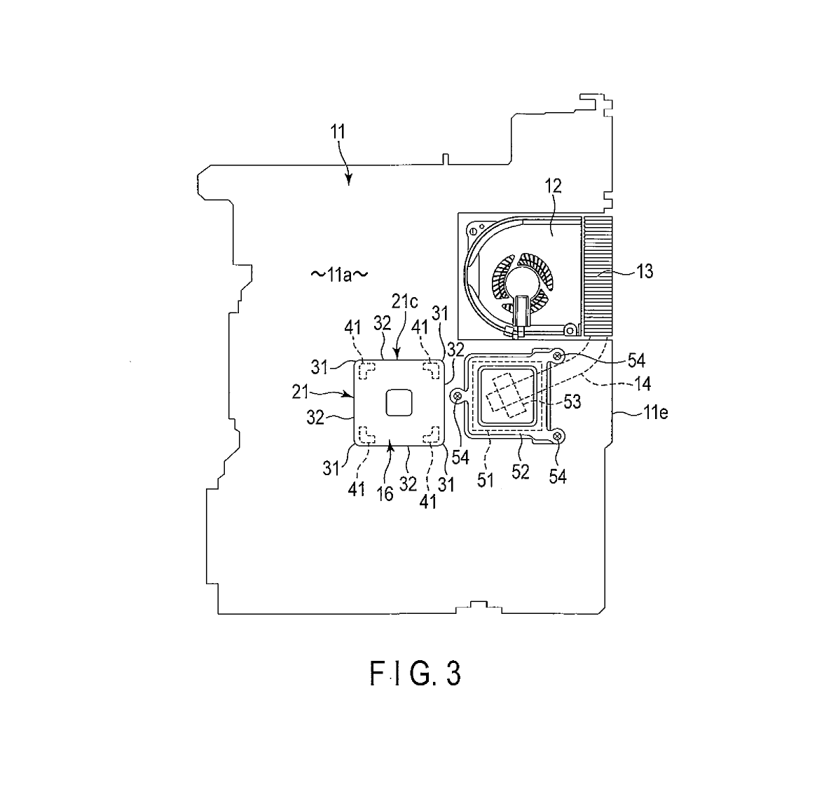

As shown in FIGS. 3, 4, and 9, the circuit board 11 includes a first surface 11a and a second surface 11b which is opposite to the first surface 11a. In this embodiment, the first surface 11a faces the rear wall of the housing 4, and the second surface 11b faces the display device 5. However, instead of this structure, the first surface 11a may face the display device 5, and the second surface 11b may face the rear wall of the housing 4.

A first component 16 is mounted on the first surface 11a. The first component 16 is, for example, a surface-mounted semiconductor component. The first component 16 is an example of a first heating component. It is supplied with power and generates heat. For example, the first component 16 generates a relatively small amount of heat and has a sufficient natural heat dissipation performance. In this embodiment, the first component 16 is not thermally connected to the heat sink 13.

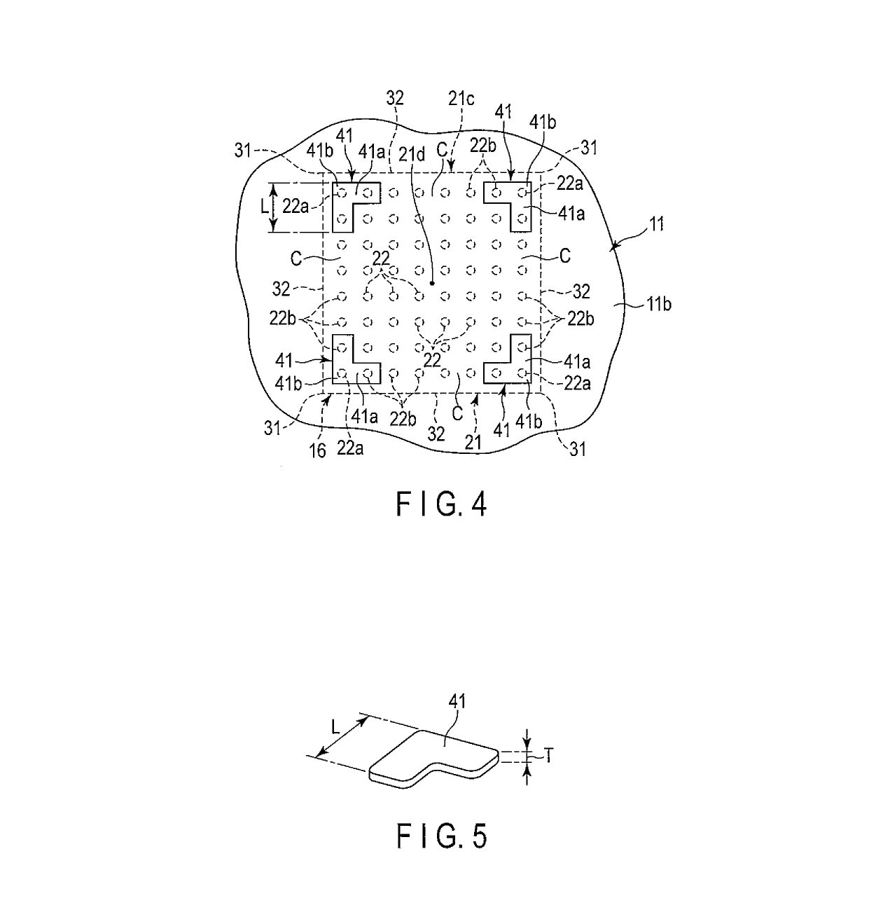

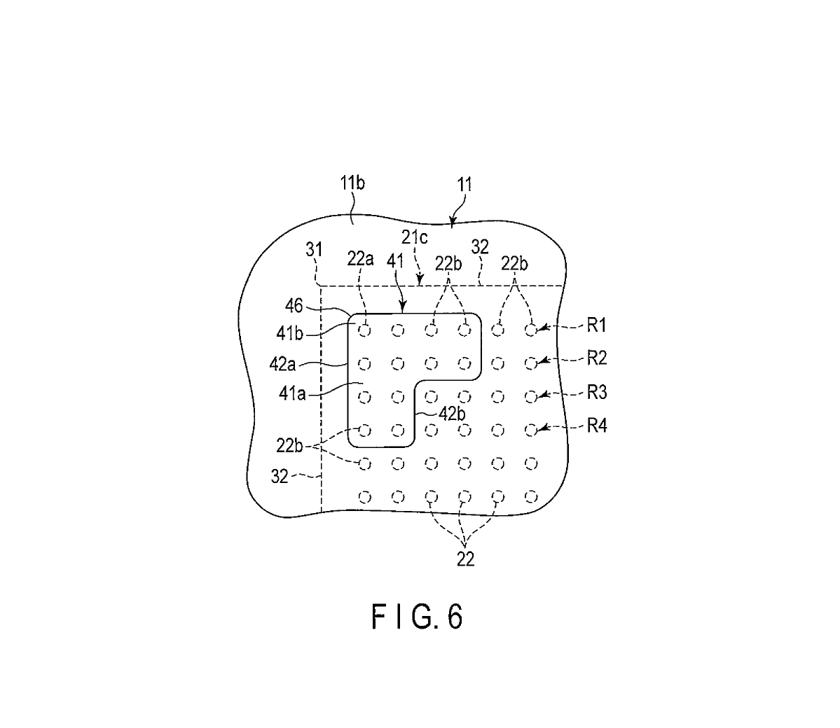

As shown in FIGS. 4, 6, and 9, an example of the first component 16 is a Ball Grid Array (BGA). The first component 16 includes a package 21 and a plurality of bumps 22 which are arranged in a lattice shape on the rear surface (i.e., lower surface) of the package 21. The numbers of bumps are different from each other in FIG. 4 and FIG. 6. FIG. 4 schematically illustrates the bumps for convenience of explanation. As an example of the actual arrangement of the bumps, as shown in FIG. 6, two columns of bumps 22 are disposed in the region of a reinforcing portion 41, which will be described below.

The package 21 includes a substrate and a semiconductor (i.e., electronic component) mounted on the substrate and is an example of a “semiconductor portion”, a “semiconductor mounting portion”, a “component mounting portion”, a “chip portion”, a “chip mounting portion”, a “substrate portion”, a “main portion”, and an “outline portion”. The bump 22 is an example of a “bonding portion”, a “connection portion”, a “solder portion”, and a “soldering portion”. The first component 16 is not limited to the BGA, but various kinds of components including an area-array-type component and other semiconductor components may be appropriately used as the first component 16.

The package 21 is a case which protects a semiconductor or an electronic component from an external environment and is an example of a sealing portion. The package 21 is not limited to a structure that completely covers the semiconductor or the electronic component, but it may be configured in such a manner that the semiconductor or electronic component is partially or entirely exposed to the outside.

As shown in FIGS. 3, 4, and 9, the package 21 has, for example, a rectangular flat box shape. The package 21 includes a first surface 21a, a second surface 21b, and an outer circumferential surface 21c (i.e., a circumferential surface, a side surface, an end portion, or a third surface). The first surface 21a is the rear surface (i.e., the rear surface of the first component 16) of the package 21 and faces the circuit board 11. A plurality of bumps 22 are provided on the first surface 21a.

The second surface 21b is on the opposite side of the first surface 21a and extends substantially in parallel to the first surface 21a. The outer circumferential surface 21c extends in a direction intersecting (i.e., substantially perpendicular to) the first surface 21a and the second surface 21b. The outer circumferential surface 21c is provided between the first surface 21a and the second surface 21b and connects the circumferential edge of the first surface 21a and the circumferential edge of the second surface 21b.

The outer circumferential surface 21c of the package 21 includes four corners 31 and four sides 32 (i.e., a straight portion, an end portion, or an edge portion) extending between the four corners 31. The four corners 31 include a first corner, a second corner, a third corner, and a fourth corner. The second corner is adjacent to the first corner. The third corner diagonally faces the first corner. The fourth corner is adjacent to the first corner and diagonally faces the second corner. As shown in FIG. 3, the four corners 31 may be rounded.

The four sides 32 include a first side, a second side, a third side, and a fourth side. The first side extends between the first corner and the second corner. The second side extends between the second corner and the third corner. The third side extends between the third corner and the fourth corner. The fourth side extends between the fourth corner and the first corner.

As shown in FIG. 4, the plurality of bumps 22 are provided on the rear surface (i.e., first surface 21a) of the package 21 and are disposed inside the outer circumferential surface 21c of the first component 16. The plurality of bumps 22 are arranged in a lattice shape along the four sides 32 of the outer circumferential surface 21c and are electrically connected to the first surface 11a of the circuit board 11.

The plurality of bumps 22 are arranged along a plurality of frame-shaped (i.e., annular) lines which are concentrically arranged. As shown in FIG. 6, the plurality of bumps 22 are classified into, for example, a first line R1 (i.e., a first column or a first circumference) serving as the outermost line (i.e., outermost circumference), a second line R2 (i.e., a second column or a second circumference) which is disposed inside the first line R1, a third line R3 (i.e., a third column or a third circumference) which is disposed inside the second line R2, and a fourth line R4 (a fourth column and a fourth circumference) which is disposed inside the third line R3.

Next, a reinforcing structure according to this embodiment will be described.

As shown in FIG. 4, the circuit board 11 includes four reinforcing portions 41 corresponding to the first component 16. The reinforcing portion 41 is an example of a “first reinforcing portion”. The reinforcing portions 41 are provided on the second surface 11b of the circuit board 11. The reinforcing portions 41 are disposed to correspond to the four corners 31 of the first component 16.

Specifically, each of the reinforcing portions 41 is, for example, an L shape smaller than the size of the first component 16. The four reinforcing portions 41 are individually provided so as to correspond to the four corners 31 and cover the rear sides of the four corners 31.

The four reinforcing portions 41 have a gap C therebetween and are individually attached to the circuit board 11. For example, the gap C between the four reinforcing portions 41 is more than the length L of one side of the reinforcing portion 41. For example, the length L is about 6.0 mm. For example, the thickness T of the reinforcing portion 41 is about 0.6 mm. The size of the reinforcing portion 41 is not limited thereto.

As shown in FIGS. 4 and 6, each of the four reinforcing portions 41 includes a first portion 41a and a second portion 41b. The first portion 41a faces the bumps 22 disposed in the first line R1 (hereinafter, referred to as the outermost line R1) among the plurality of bumps 22. That is, the first portion 41a is provided on the rear side (i.e., rear) of the bumps 22 disposed in the outermost line R1 and covers the rear surfaces of the bumps 22 disposed in the outermost line R1.

The second portion 41b is provided outside the bumps 22 disposed in the outermost line R1. In the specification, a side which is away from the center 21d (i.e., base point) of the package 21 is defined as the outside and a side which is close to the center 21d is defined as the inside. That is, the second portion 41b is disposed outside the bumps 22 disposed in the outermost line R1 with respect to the center 21d of the package 21.

As shown in FIG. 6, a plurality of bumps 22 disposed in the outermost line R1 include a first bump 22a and a plurality of second bumps 22b. The first bump 22a is an example of a “first bonding portion (i.e., a first connection portion or a first solder portion)”. The first bump 22a is a so-called corner bump corresponding to the corner 31 of the package 21. The first bump 22a is disposed at the corner of a plurality of bumps 22 arranged in a frame shape.

The first bump 22a is disposed in the vicinity of the corner 31 of the package 21. Among the plurality of bumps 22, the first bump 22a is closest to the corner 31 of the package 21. That is, the first component 16 includes four first bumps 22a. The four first bumps 22a are disposed in the vicinity of the corresponding four corners 31.

The second bump 22b is an example of a “second bonding portion (i.e., a second connection portion or a second solder portion)”. The second bump 22b is further away from the corner 31 of the package 21 than the first bump 22a. The second bumps 22b are arranged along the side 32 of the package 21.

As shown in FIGS. 4 and 6, the reinforcing portion 41 faces the first bump 22a and does not face at least one second bump 22b. That is, the gap C between the reinforcing portions 41 is provided on the rear side of some of the second bumps 22b. The reinforcing portion 41 is formed in an L shape along the outer circumferential surface 21c of the package 21. That is, the reinforcing portion 41 is formed in an L shape along the corner 31 of the package 21.

As shown in FIG. 6, the reinforcing portion 41 covers (i.e., faces) the bumps 22 disposed in the outermost line R1 and some of the bumps 22 disposed in the second line R2. The size of the reinforcing portion 41 is not limited thereto. The reinforcing portion 41 may have a small size capable of covering only the bumps 22 disposed in the outermost line R1 or a large size capable of covering the bumps 22 in the outer line R1 to the bumps 22 in the third line R3.

As shown in FIG. 6, the reinforcing portion 41 includes a first edge portion 42a (i.e., first end portion) serving as the outer edge and a second edge portion 42b (i.e., second end portion) serving as the inner edge. The first edge portion 42a is arranged along the bumps 22 disposed in the outermost line R1 (i.e., along the arrangement of the bumps 22). The first edge portion 42a is located between the bumps 22 in the outermost line R1 and the outer circumferential surface 21c of the package 21.

An example of the reinforcing portion 41 is a metal plate (i.e., metal piece). Pads are provided on the second surface 11b of the circuit board 11. For example, the reinforcing portions 41 are soldered to the pads and are fixed to the circuit board 11.

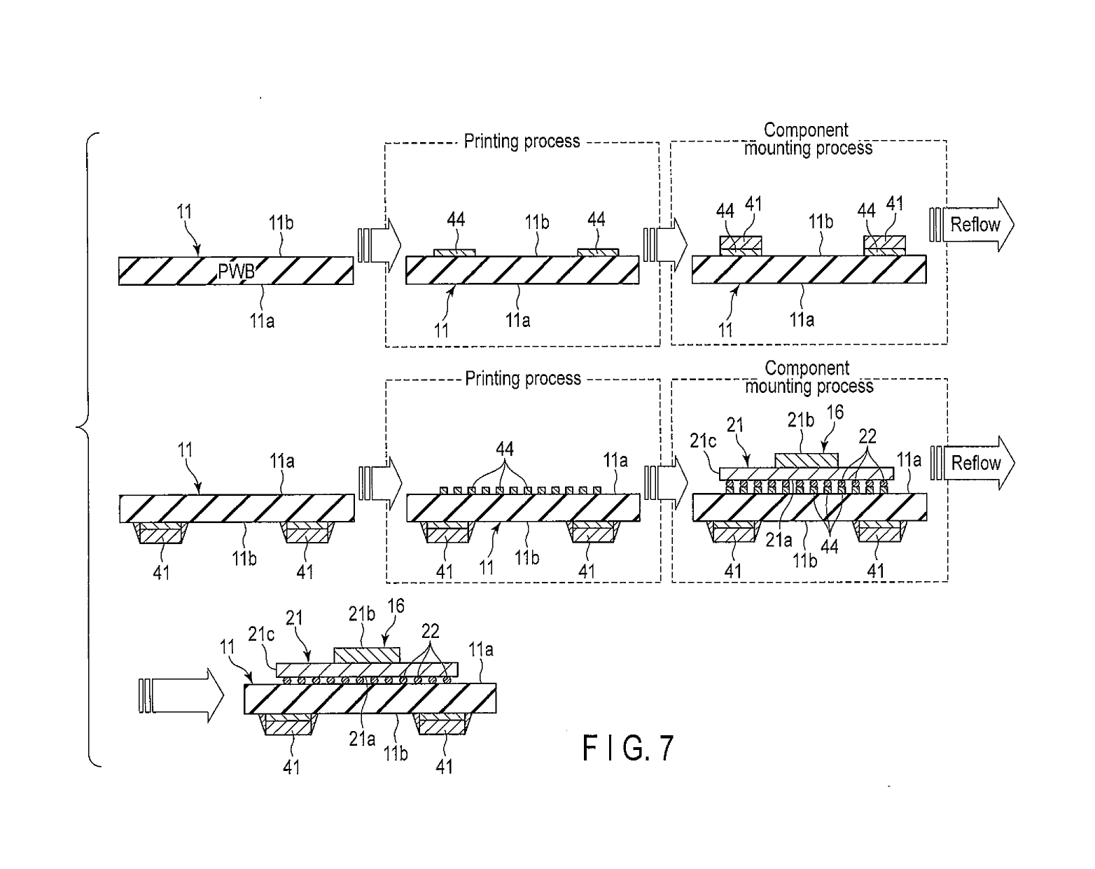

FIG. 7 shows an example of a process of mounting the reinforcing portion 41. As shown in FIG. 7, first, the circuit board 11 is prepared. Then, in a first printing process, solder 44 (i.e., solder paste) is printed on the second surface 11b of the circuit board 11. Then, in a first component mounting process, the reinforcing portions 41 are mounted. In a first reflow process, the reinforcing portions 41 are fixed to the second surface 11b. That is, the reinforcing portions 41 and other components are mounted on the second surface 11b in a surface mounting process.

Then, in a second printing process, the solder 44 is printed on the first surface 11a of the circuit board 11. Then, in a second component mounting process, the first component 16 is mounted. In a second reflow process, the first component 16 is mounted on the first surface 11a. In this way, the circuit board 11 is completed.

The reinforcing portion 41 is made of a material with a linear expansion coefficient close to that of the circuit board 11 and is made of, for example, stainless steel (i.e., SUS). Therefore, in the reflow process, the reinforcing portion 41 is expanded and contracted, following the thermal expansion/contraction of the circuit board 11. As a result, a large amount of stress is less likely to be applied to the circuit board 11.

The material forming the reinforcing portion 41 is not limited to the above-mentioned example. The reinforcing portion 41 may be made of, for example, a resin material or the same material as that forming the circuit board. In addition, the reinforcing portion 41 may be an adhesive or solder which is applied onto the circuit board 11 and is then cured.

Next, a second component 51 and a second reinforcing portion 52 will be described.

As shown in FIG. 3, the circuit board 11 includes the second component 51. The second component 51 is provided between the first component 16 and an end portion 11e (i.e., edge portion) of the circuit board 11. In this embodiment, the second component 51 is provided on the second surface 11b of the circuit board 11. The second component 51 may be provided on the first surface 11a, instead of the second surface 11b.

The second component 51 is an example of a second heating component, and it is supplied with power and generates heat. The amount of heat generated by the second component 51 is greater than the amount of heat generated by the first component 16. The second component 51 is thermally connected to the heat sink 13 through the thermally-conductive member 14. An example of the thermally-conductive member 14 is a heat pipe. The heat sink 13 faces the exhaust hole 6 of the housing 4. The heat sink 13 is cooled by wind from the fan 12.

As shown in FIG. 2, the second reinforcing portion 52 is provided as another reinforcing portion on the rear side of the second component 51. That is, in this embodiment, the second reinforcing portion 52 is provided on the first surface 11a of the circuit board 11. When the second component 51 is provided on the first surface 11a, the second reinforcing portion 52 is provided on the second surface 11b. The size of the second reinforcing portion 52 is greater than that of the second component 51 and covers the entire line (i.e., the entire circumferential edge, the outline, or both end portions) of the second component 51. The second reinforcing portion 52 is formed in a frame shape along the outline of the second component 51.

A pressing portion 53 is attached to the thermally-conductive member 14. The pressing portion 53 presses the thermally-conductive member 14 against the second component 51 to increase the thermal connection between the thermally-conductive member 14 and the second component 51. The pressing portion 53 is fixed to the circuit board 11 by a plurality of fixing portions (e.g., fixing members, for example, screws).

For example, the fixing portions pass through the circuit board 11 and are fixed to the second reinforcing portion 52. The second reinforcing portion 52 supports, for example, the plurality of fixing portions and supports the pressing portion 53. That is, the pressing portion 53 is fixed to the second reinforcing portion 52. The rigidity of the second reinforcing portion 52 is greater than that of the reinforcing portion 41. The second reinforcing portion 52 is fixed to the circuit board 11 by fixing portions 54 (e.g., fixing members, for example, screws).

The second reinforcing portion 52 is provided between the first component 16 and the end portion 11e (i.e., edge portion) of the circuit board 11. That is, the first component 16 is closer to the inside (i.e., center) of the circuit board 11 than the second reinforcing portion 52.

According to this structure, it is possible to improve impact resistance.

When a reinforcing plate (e.g., back plate) is provided on the rear side of the component on the circuit board, the reinforcing plate is generally larger than the component and is sufficient to cover the entire component. In this way, the rigidity of the circuit board increases and the component is protected.

However, the inventors found that, in some cases, an increase in the rigidity of the circuit board was not connected with the protection of the component. Specifically, the inventors tested the lifespan of two boards on which the same component was mounted. The two boards are a first board and a second board which is thicker than the first board (i.e., the second board has a rigidity greater than that of the first board). An impacting force was repeatedly applied to the two boards (e.g., a drop test) and the number of times which a defect occurred in the circuit board was counted.

In general, it is considered that the second board with greater rigidity has a longer circuit board lifespan (i.e., a longer component lifespan). However, the test proved that the lifespan of the second board was shorter than that of the first board.

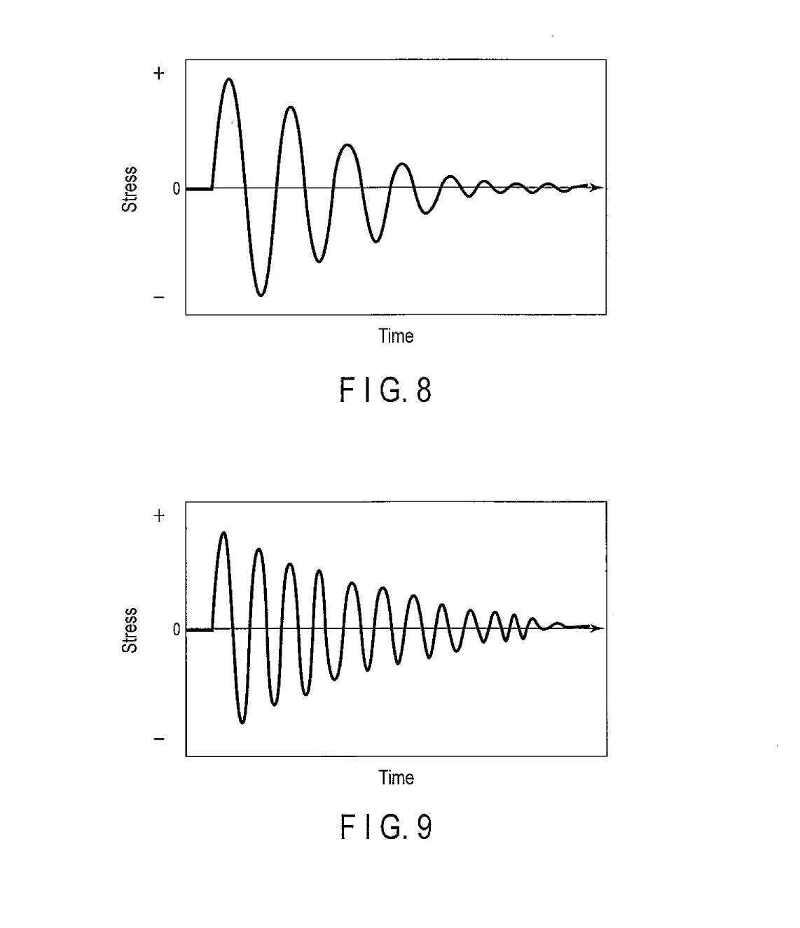

The inventors analyze the reason as follows. That is, FIG. 8 shows an aspect in which an impacting force is applied to the circuit board with low rigidity. When an impacting force is applied to the circuit board, stress which oscillates with a predetermined amplitude is repeatedly applied as vibration on the circuit board. In the circuit board with lower rigidity, the peak of the stress increases, but the number of times (i.e., the number of waves in FIG. 8) stress is repeatedly applied tends to be reduced.

FIG. 9 shows an aspect in which an impacting force is applied to a circuit board with high rigidity. In the circuit board with high rigidity, the peak of stress is reduced, but the number of times (i.e., the number of waves in FIG. 9) stress is repeatedly applied tends to increase. Therefore, for the lifespan, the number of times stress is repeatedly applied when an impacting force is input is one of the important factors, and it is considered that stress is more likely to be applied to the circuit board with high rigidity, which results in a reduction in the lifespan of the circuit board.

As can be seen from the above, the structure in which the reinforcing plate is attached to the entire component is effective for a static load, but is less effective for vibration and impact (or heat) than that according to the related art, which may cause a reduction in the lifespan of the circuit board. Therefore, in this embodiment, the reinforcing portion 41 is provided which is capable of suppressing an increase in the rigidity of the circuit board as much as possible and preventing the damage of the circuit board.

That is, the structure according to this embodiment includes the component 16 which is mounted on the first surface 11a of the circuit board 11 and has the corners 31 and the reinforcing portions 41 which are provided on the second surface 11b of the circuit board 11 so as to correspond to the corners 31. That is, the reinforcing portions 41 do not cover the entire rear surface of the component 16 but protect the corners 31 of the component 16 on which stress is most likely to be concentrated. In this way, it is possible to protect the component 16 and improve impact resistance without excessively increasing the rigidity of the circuit board 11.

In addition, in this embodiment, the component 16 includes the package 21 having the corners 31 and a plurality of bumps 22 arranged in a lattice shape. Among the plurality of bumps 22, the bumps 22 disposed in the outermost line include the first bump 22a and a plurality of second bumps 22b which are further away from the corner 31 than the first bump 22a. The reinforcing portion 41 includes the portion 41b which is disposed outside the first bump 22a with respect to the center of the package 21.

In this way, the reinforcing portion 41 can receive a stress wave which is transmitted from the end portion 11e of the circuit board 11 to the first bump 22a through the circuit board 11 at the outside of the first bump 22a. In this way, it is possible to shift the stress-concentrated portion to the outside of the first bump 22a. Therefore, it is possible to reduce the stress of the first bump 22a on which stress is most likely to be concentrated and thus improve impact resistance.

In this embodiment, the reinforcing portion 41 does not cover at least one second bump 22b. In this way, it is possible to reduce the rigidity of the circuit board 11, as compared to the structure according to the related art in which the reinforcing plate covers the entire rear surface of the component.

In this embodiment, the four reinforcing portions 41 are provided. The four reinforcing portions 41 are individually provided so as to correspond to the four corners 31 of the component 16. In this way, it is possible to appropriately protect the four corners 31 of the component 16 and improve impact resistance.

In this embodiment, each of the four reinforcing portions 41 include the portion 41a which faces the bumps 22 in the outermost line R1. That is, the reinforcing portion 41 is provided on the rear side of the bumps 22 disposed in the outermost line R1. In this way, it is possible to reduce the stress of the bumps 22 disposed in the outermost line R1 on which stress is most likely to be concentrated and thus improve impact resistance.

In this embodiment, the bumps 22 in the outermost line include the first bump 22a which is disposed in the vicinity of one of the four corners 31 and a plurality of second bumps 22b which are further away from the corner 31 than the first bump 22a. The reinforcing portion 41 faces the first bump 22a and does not face at least one of the second bumps 22b. According to this structure, it is possible to reduce the stress of the first bump 22a on which stress is most likely to be concentrated among the bumps 22 disposed in the outermost line R1 and thus improve impact resistance.

In this embodiment, the edge portion 42a of the reinforcing portion 41 is arranged along the bumps 22 in the outermost line R1. According to this structure, it is possible to further reduce the stress of the bumps 22 in the outermost line R1. In this embodiment, the edge portion 42a of the reinforcing portion 41 is disposed between the bumps 22 of the outermost line R1 and the outer circumferential surface 21c of the first component 16. That is, the reinforcing portions 41 are provided inside the edge of the rear surface (i.e., first surface 11a) of the first component 16. According to this structure, it is possible to effectively use the mounting area of the circuit board 11.

In this embodiment, the corner 46 of the edge portion 42a of the reinforcing portion 41 is rounded. According to this structure, it is possible to distribute stress applied from the outside to the corner 46 of the reinforcing portion 41 and reduce the concentration of stress on the corner 46. Therefore, it is possible to further improve impact resistance.

In this embodiment, the reinforcing portions 41 are soldered to the circuit board 11. According to this structure, a hole, such as a screw hole, is not needed and it is possible to ensure a large wiring space in the inner layer of the circuit board 11. In the case of mounting the reinforcing portions 41 and other components by a surface mounting process, it is not necessary to employ a screwing process or to use jig for a back plate. In addition, a post process using, for example, an adhesive, a tape, or a screw is not needed. This contributes to reducing manufacturing costs.

In this embodiment, the reinforcing portion 41 is made of a material with a linear expansion coefficient close to that of the circuit board, such as stainless steel. According to this structure, it is possible to reduce the influence of thermal stress on the first component 16.

When plating is performed on a small component, such as the reinforcing portion 41, a plurality of reinforcing portions 41 are likely to be stuck to each other. Therefore, in this embodiment, plating (e.g., tin plating) is performed on the reinforcing portion 41 with a nickel base while vibration is being applied to the reinforcing portion 41. The vibration during plating makes it possible to prevent a plurality of reinforcing portions 41 from attaching to each other.

In this embodiment, the reinforcing portion 41 has an L shape along the corner 31 of the component 16. According to the L-shaped reinforcing portion 41, it is possible to appropriately protect the corner 31 of the component 16 and obtain a relatively high material yield. In addition, the reinforcing portion 41 is not limited to the L-shape, but may have a rectangular shape, a triangular shape, or other shapes.

In this embodiment, the circuit board 11 includes the second component 51 that is provided on the first surface 11a or the second surface 11b between the first component 16 and the end portion 11e (i.e., edge portion) of the circuit board 11 and the second reinforcing portion 52 that is provided on the rear side of the second component 51 and covers the entire circumference of the second component 51.

According to this structure, the vicinity of the end portion 11e of the circuit board 11 to which an impacting force is likely be applied from the outside is reinforced by the second reinforcing portion 52 with a high rigidity and the vicinity of the center of the circuit board 11 to which an impacting force is less likely to be directly applied from the outside is reinforced by the first reinforcing portion 41 with a lower rigidity. In this way, it is possible to reinforce the necessary portions without increasing the rigidity of the entire circuit board 11.

Next, some modifications of the reinforcing portion 41 will be described.

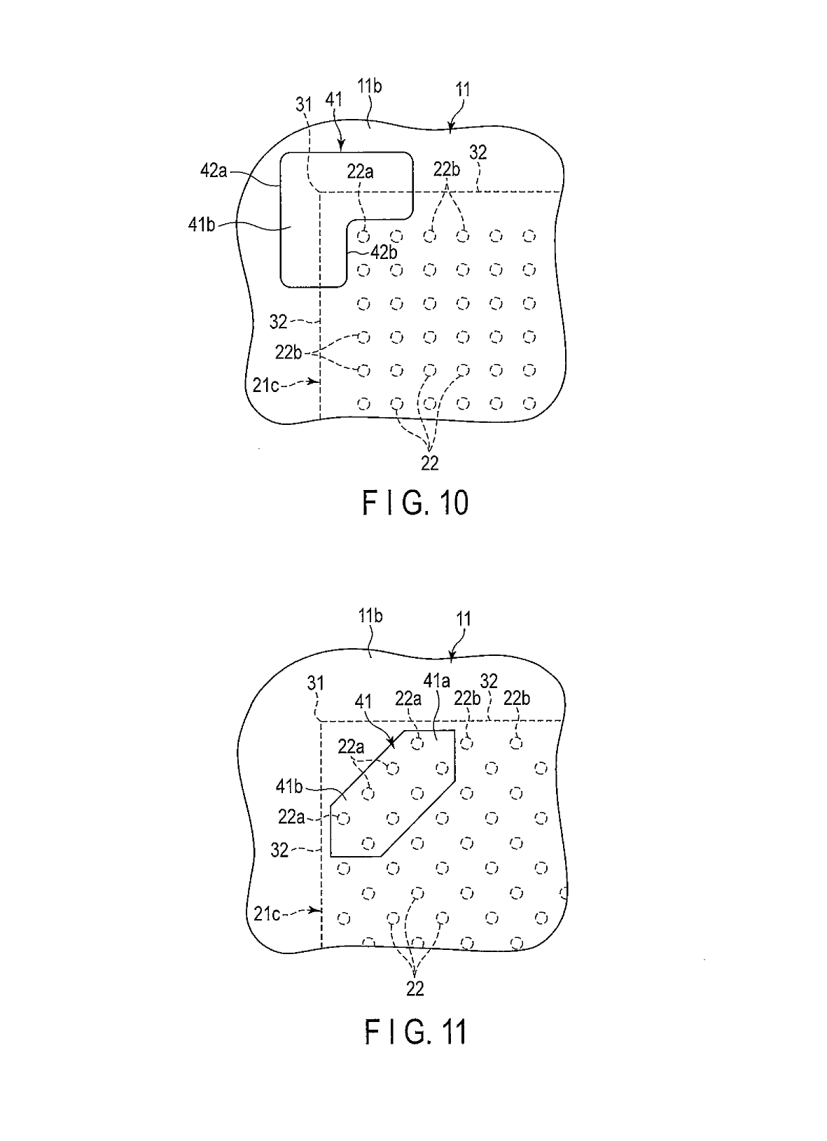

FIG. 10 shows a first modification of the reinforcing portion 41. As shown in FIG. 10, in the first modification, the entire reinforcing portion 41 is disposed outside the bumps 22 in the outermost line R1. That is, the reinforcing portion 41 does not cover the bump 22. According to the structure of the reinforcing portion 41, the reinforcing portion 41 receives a stress wave which is transmitted from the end portion 11e of the circuit board 11 to the first bump 22a through the circuit board 11 at the outside of the first bump 22a.

In this way, it is possible to reduce the stress of the bump 22 and thus improve impact resistance. However, the first embodiment in which the reinforcing portion 41 is disposed even on the rear side of the bump 22 can improve impact resistance to a level higher than that of the first modification.

FIG. 11 shows a second modification of the reinforcing portion 41. As shown in FIG. 11, in the second modification, a plurality of first bumps 22a are provided so as to correspond to the corner 31 of the package 21. For example, the first bumps 22a are obliquely arranged with respect to the corner 31 of the package 21. According to this structure, it is possible to improve impact resistance.

Next, second to twelfth embodiments will be described. In the following embodiments, components having the same or similar functions as those in the first embodiment are denoted by the same reference numerals and a description thereof will not be repeated.

### Second Embodiment

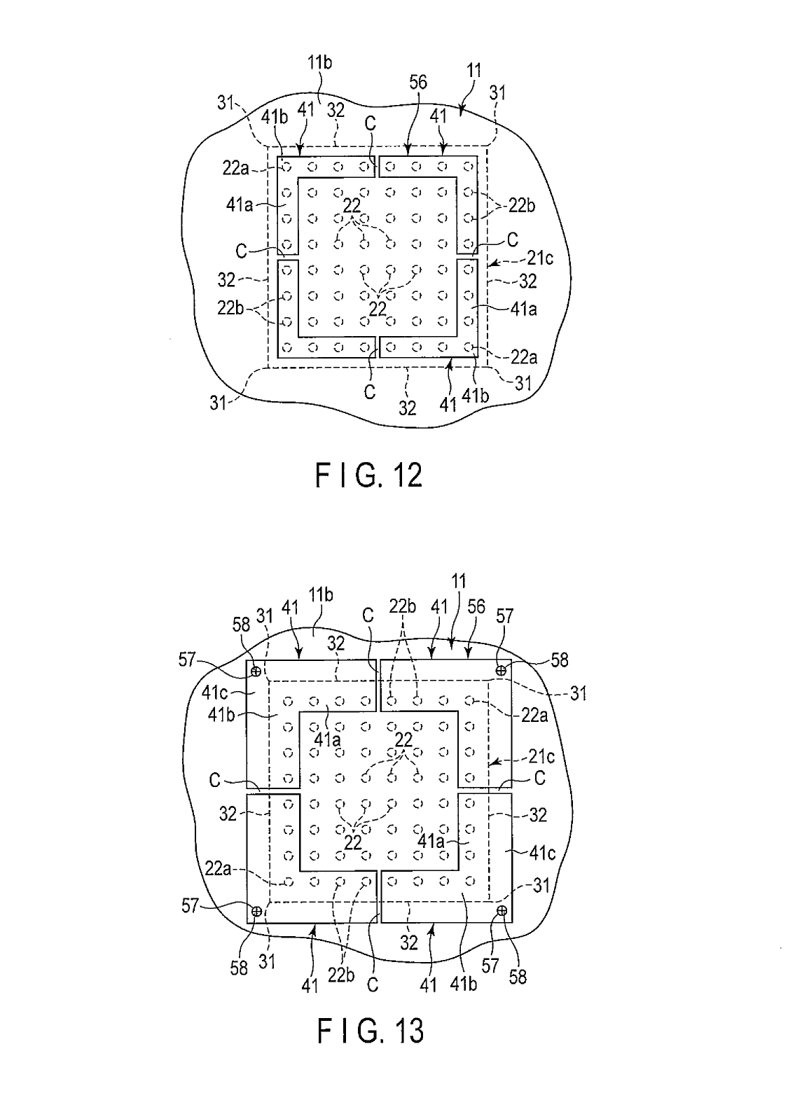

Next, a reinforcing portion 41 according to the second embodiment will be described with reference to FIG. 12. Structures other than the following structures are the same as those in the first embodiment.

The reinforcing portion 41 according to this embodiment is formed by dividing a large reinforcing portion 56 provided along the outline of a first component 16 into four small reinforcing portions 41. That is, slits are provided in a large reinforcing portion 56 at positions corresponding to the substantial centers of the four sides 32 of the first component 16 and the large reinforcing portion 56 is cut into four individual reinforcing portions 41.

According to this structure, since the four reinforcing portions 41 are cut, the rigidity of the four reinforcing portions 41 is lower than that of the large reinforcing portion 56. Therefore, it is possible to reduce the stress applied to bumps 22 while suppressing an increase in the rigidity of a circuit board 11. In this way, it is possible to improve impact resistance.

### Third Embodiment

Next, a reinforcing portion 41 according to the third embodiment will be described with reference to FIG. 13. Structures other than the following structures are the same as those in the second embodiment.

The reinforcing portion 41 according to this embodiment includes third portions 41c which are disposed outside the first component 16. An attachment portion 57 fixed to a circuit board 11 is provided in each of the third portions 41c. Attachment portions 57 are fixed to the circuit board 11 by fixing portions 58 (e.g., fixing members, for example, screws).

According to this structure, similarly to the second embodiment, it is possible to improve impact resistance.

### Fourth Embodiment

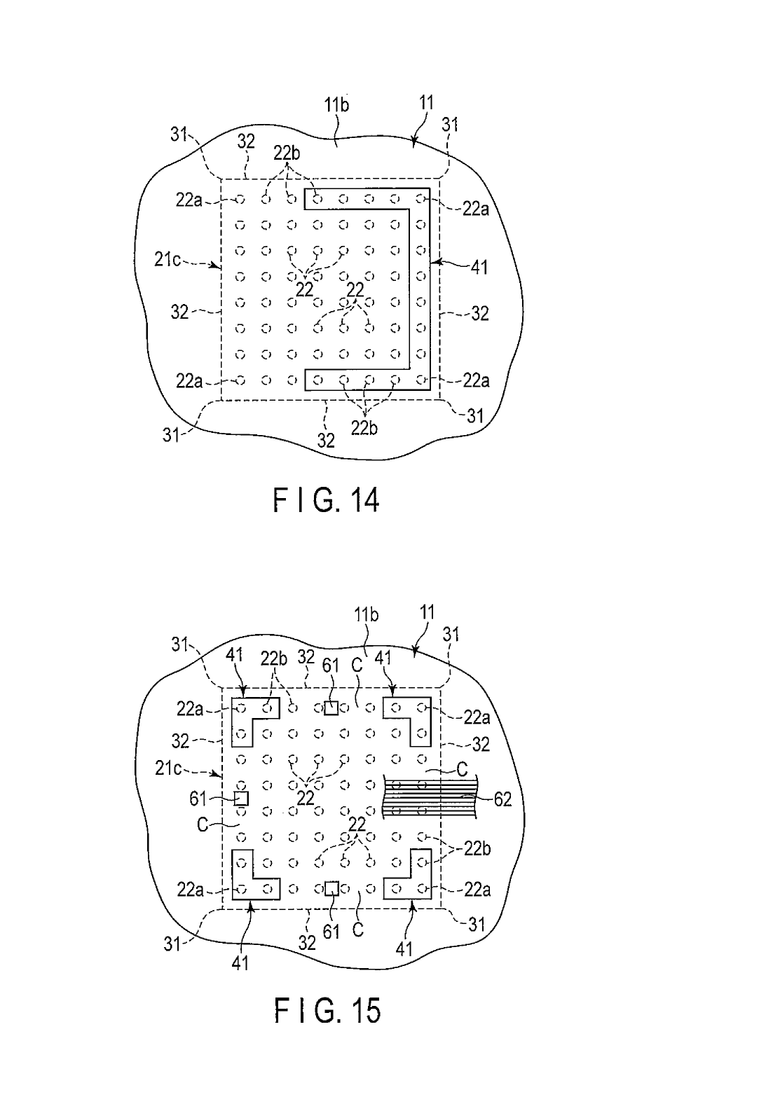

Next, a reinforcing portion 41 according to the fourth embodiment will be described with reference to FIG. 14. Structures other than the following structures are the same as those in the first embodiment.

The reinforcing portion 41 according to this embodiment does not cover the entire circumference of a first component 16, and at least a portion of the reinforcing portion 41 is removed. The reinforcing portion 41 is provided so as to correspond to some of four sides 32 of the first component 16. For example, the reinforcing portion 41 according to this embodiment is provided so as to correspond to three sides 32 of the first component 16. The reinforcing portion 41 may be provided so as to correspond to one side 32 or two sides 32 of the first component 16.

According to this structure, similarly to the second embodiment, it is possible to improve impact resistance.

### Fifth Embodiment

Next, a reinforcing portion 41 according to the fifth embodiment will be described with reference to FIG. 15. Structures other than the following structures are the same as those in the first embodiment.

In this embodiment, a circuit board 11 includes other components 61 (e.g., electronic components) and a wiring pattern 62 between a plurality of reinforcing portions 41. That is, the components 61 and the wiring pattern 62 are provided in the gap C between the reinforcing portions 41. An example of the component 61 is a chip component, such as a capacitor or a chip resistor. However, the component 61 is not limited thereto.

According to this structure, similarly to the first embodiment, it is possible to improve impact resistance. In addition, according to this embodiment, other components 61 or the wiring pattern 62 is provided in the gap C between the reinforcing portions 41. This contributes to mounting components on the circuit board 11 with high density.

### Sixth Embodiment

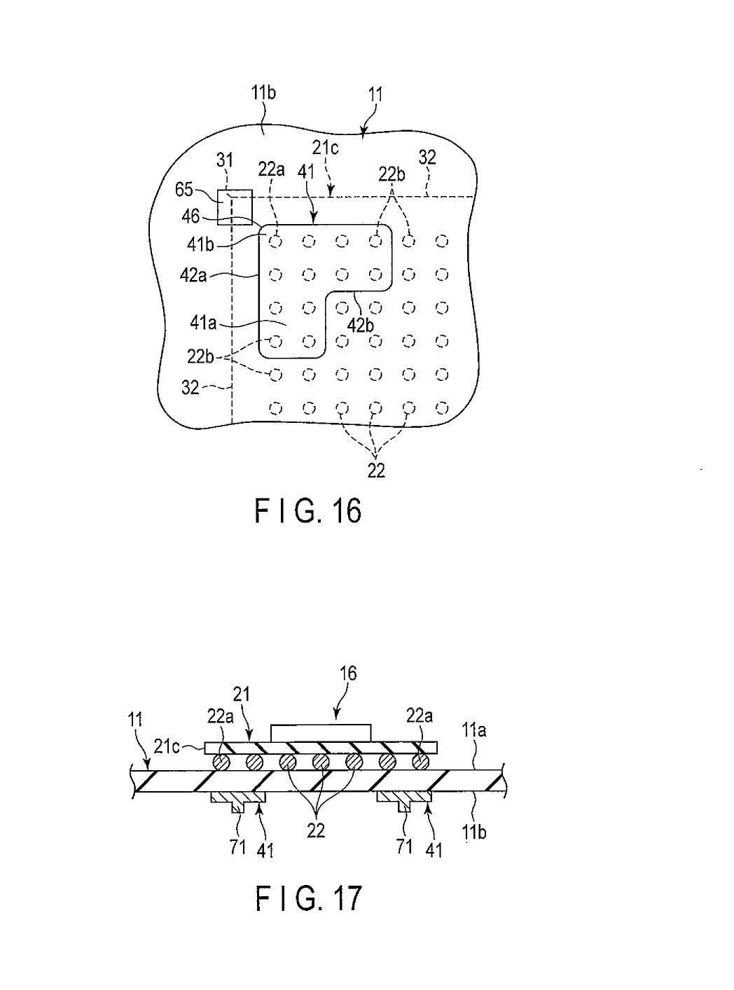

Next, a reinforcing portion 41 according to the sixth embodiment will be described with reference to FIG. 16. Structures other than the following structures are the same as those in the first embodiment.

In this embodiment, the corner 46 of a first edge portion 42a of the reinforcing portion 41 is rounded. A circuit board 11 has a component 65 (e.g., electronic component) provided in a region adjacent to the corner 46 of the reinforcing portion 41. The component 16 is disposed in the vicinity of the corner 46 of the reinforcing portion 41 and faces the corner 46 of the reinforcing portion 41. An example of the component 65 is a chip component, such as a capacitor or a chip resistor. However, the component 65 is not limited thereto.

According to this structure, similarly to the first embodiment, it is possible to improve impact resistance. In addition, according to this embodiment, the component 65 is mounted in the region adjacent to the corner 46 of the reinforcing portion 41. Since the corner 46 of the reinforcing portion 41 is rounded, it is possible to arrange the component 65 in the vicinity of the reinforcing portion 41. This contributes to mounting components on the circuit board 11 with high density.

### Seventh Embodiment

Next, a reinforcing portion 41 according to the seventh embodiment will be described with reference to FIG. 17. Structures other than the following structures are the same as those in the first embodiment.

The reinforcing portion 41 according to this embodiment is made of a material with high thermal conductivity, such as metal. As shown in FIG. 17, a protrusion 71 (e.g., fin) is provided on the reinforcing portion 41 in order to increase a heat dissipation area. For example, the protrusion 71 protrudes in the thickness direction of the reinforcing portion 41 (i.e., the thickness direction of the circuit board 11). The reinforcing portion 41 is thermally connected to bumps 22 of a first component 16 through the circuit board 11 and receives heat from the bumps 22 of the first component 16. The reinforcing portion 41 functions as an example of a heat dissipation portion that accelerates the dissipation of heat from the first component 16.

According to this structure, similarly to the first embodiment, it is possible to improve impact resistance. In addition, according to this embodiment, the reinforcing portion 41 including the protrusion 71 makes it possible to accelerate the dissipation of heat from the first component 16. In this way, it is also possible to improve the heat dissipation performance.

The protrusion 71 may be formed separately from the reinforcing portion 41. The protrusion 71 may be a supporting portion or a fixing portion for something, or it may be provided only in order to dissipate heat.

### Eighth Embodiment

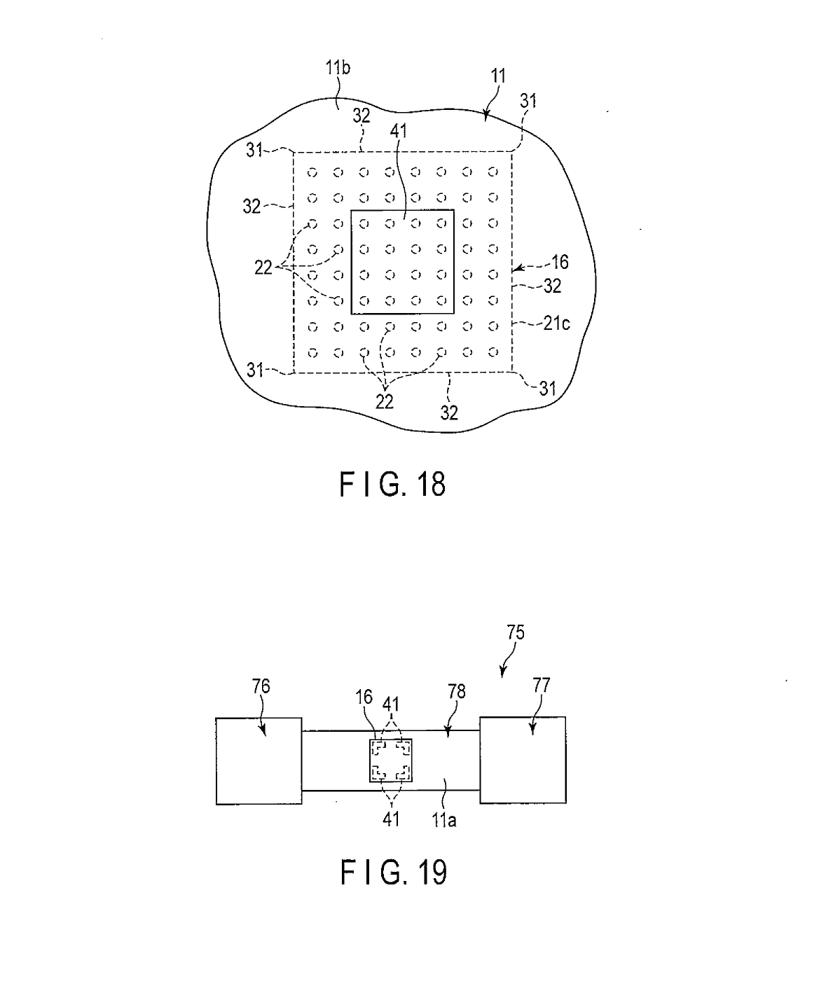

Next, a reinforcing portion 41 according to the eighth embodiment will be described with reference to FIG. 18. Structures other than the following structures are the same as those in the seventh embodiment.

The reinforcing portion 41 according to this embodiment is provided so as to correspond to the center of a first component 16. The reinforcing portion 41 is made of a material with high thermal conductivity, such as metal, and is thermally connected to bumps 22 of the first component 16. The reinforcing portion 41 functions as an example of a heat dissipation portion that accelerates the dissipation of heat from the first component 16.

According to this structure, it is possible to improve impact resistance. In addition, according to this embodiment, it is possible to accelerate the dissipation of heat from the first component 16.

### Ninth Embodiment

Next, a reinforcing portion 41 according to the ninth embodiment will be described with reference to FIG. 19. Structures other than the following structures are the same as those in the first embodiment.

The housing 4 has a board unit 75 accommodated therein. The board unit 75 includes a first rigid board 76, a second rigid board 77, and a flexible printed wiring board 78. The first rigid board 76 is separated from the second rigid board 77. The flexible printed wiring board 78 is provided between the first rigid board 76 and the second rigid board 77. That is, the flexible printed wiring board 78 extends between the first rigid board 76 and the second rigid board 77 and electrically connects the first rigid board 76 and the second rigid board 77.

A component 16 is mounted on a first surface 11a of the flexible printed wiring board 78. Four reinforcing portions 41 are provided on a second surface 11b of the flexible printed wiring board 78. Similarly to the first embodiment, the four reinforcing portions 41 are provided so as to correspond to the four corners 31 of the component 16 and protect the component 16.

According to this structure, similarly to the first embodiment, it is possible to improve impact resistance. In addition, according to this embodiment, it is possible to protect the component 16 while maintaining the flexibility of the flexible printed wiring board 78. That is, when a large reinforcing portion is provided so as to cover the entire circumference of the component 16, the flexibility of the flexible printed wiring board 78 is damaged. As a result, the flexible printed wiring board 78 is not nearly deformed.

In this embodiment, the four reinforcing portions 41 are provided so as to correspond to the four corners 31 of the component 16. Therefore, it is possible to protect the component 16 while maintaining the flexibility of the flexible printed wiring board 78.

### Tenth Embodiment

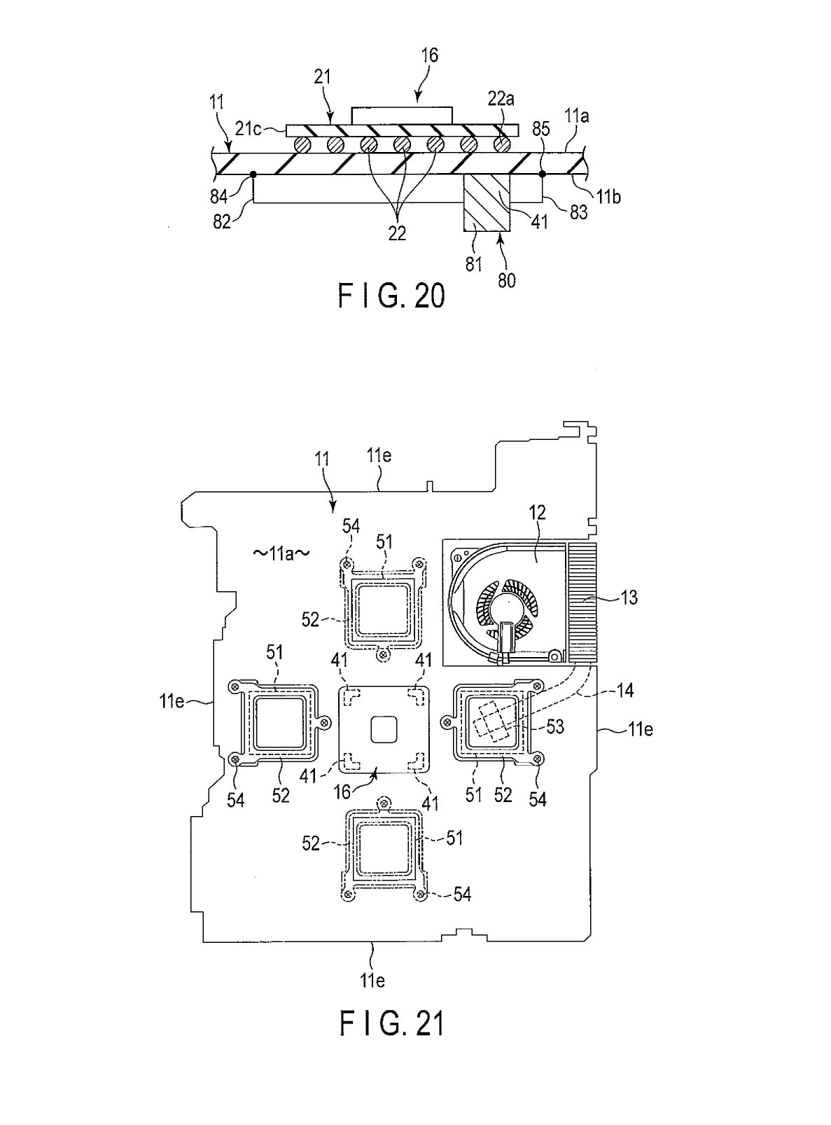

Next, a reinforcing portion 41 according to the tenth embodiment will be described with reference to FIG. 20. Structures other than the following structures are the same as those in the first embodiment.

In this embodiment, a second component 80 is mounted as another component on a second surface 11b of a circuit board 11. FIG. 20 schematically shows the second component 80 for convenience of explanation. The second component 80 is larger than a first component 16. The second component 80 includes a first portion 81, a second portion 82, and a third portion 83. The first portion 81 is disposed on the rear side of the first component 16. The second portion 82 deviates from the rear side of the first component 16 and does not overlap the first component 16. The third portion 83 is disposed opposite to the second portion 82. The third portion 83 deviates from the rear side of the first component 16 and does not overlap the first component 16.

The first portion 81 includes a portion (i.e., a contact portion, a supporting portion, a reinforcing portion, or a surface portion) which comes into contact with the second surface 11b of the circuit board 11 on the rear side of the first component 16. That is, the first portion 81 has a surface (i.e., plane) which comes into contact with the circuit board 11. The first portion 81 supports the circuit board 11 with its surface.

The first portion 81 is disposed on the rear side of bumps 22 in the outermost line R1 of the first component 16, specifically, the rear side of a first bump 22a (i.e., corner bump). The first portion 81 substantially has the same function as the reinforcing portion 41 according to the first embodiment.

The second portion 82 includes a first electric connection portion 84 which is electrically connected to the circuit board 11. The third portion 83 includes a second electric connection portion 85 which is electrically connected to the circuit board 11. The first portion 81 is not electrically connected to the circuit board 11. An example of the second component 80 is a connector.

According to this structure, similarly to the first embodiment, it is possible to improve impact resistance.

Next, an electronic apparatus will be additionally described.

An electronic apparatus according to an embodiment comprises a housing, a circuit board, a first component, and a second component. The circuit board is in the housing and comprises a first surface and a second surface which is opposite to the first surface. The first component is mounted on the first surface of the circuit board. The second component comprises a first portion that comes into surface contact with a region corresponding to the first component in the second surface of the circuit board and is not electrically connected to the circuit board and a second portion that is electrically connected to the circuit board in a region which deviates from the first component in the second surface of the circuit board.

### Eleventh Embodiment

Next, a reinforcing portion 41 according to the eleventh embodiment will be described with reference to FIG. 21. Structures other than the following structures are the same as those in the first embodiment.

In this embodiment, a circuit board 11 includes a plurality of second components 51 and a plurality of second reinforcing portions 52. The second components 51 and the second reinforcing portions 52 are provided between a first component 16 and an end portion 11e (i.e., edge portion) of the circuit board 11. The plurality of second components 51 and the plurality of second reinforcing portions 52 are arranged on both sides of (or around) the first component 16 such that the first component 16 is interposed between the second components 51 and the second reinforcing portions 52. That is, the first component 16 and the first reinforcing portions 41 are provided in a region surrounded by the plurality of second components 51 and the plurality of second reinforcing portions 52. The number of second components 51 and the number of second reinforcing portions 52 may be 2, or 3 or more.

According to this structure, similarly to the first embodiment, it is possible to improve impact resistance. According to this embodiment, the first component 16 and the first reinforcing portions 41 are provided at the center portion of the circuit board 11 which is surrounded by the second reinforcing portions 52 and to which an external impacting force is less likely to be applied. According to this structure, it is possible to reinforce a necessary portion while suppressing an increase in the rigidity of the entire circuit board 11.

### Twelfth Embodiment

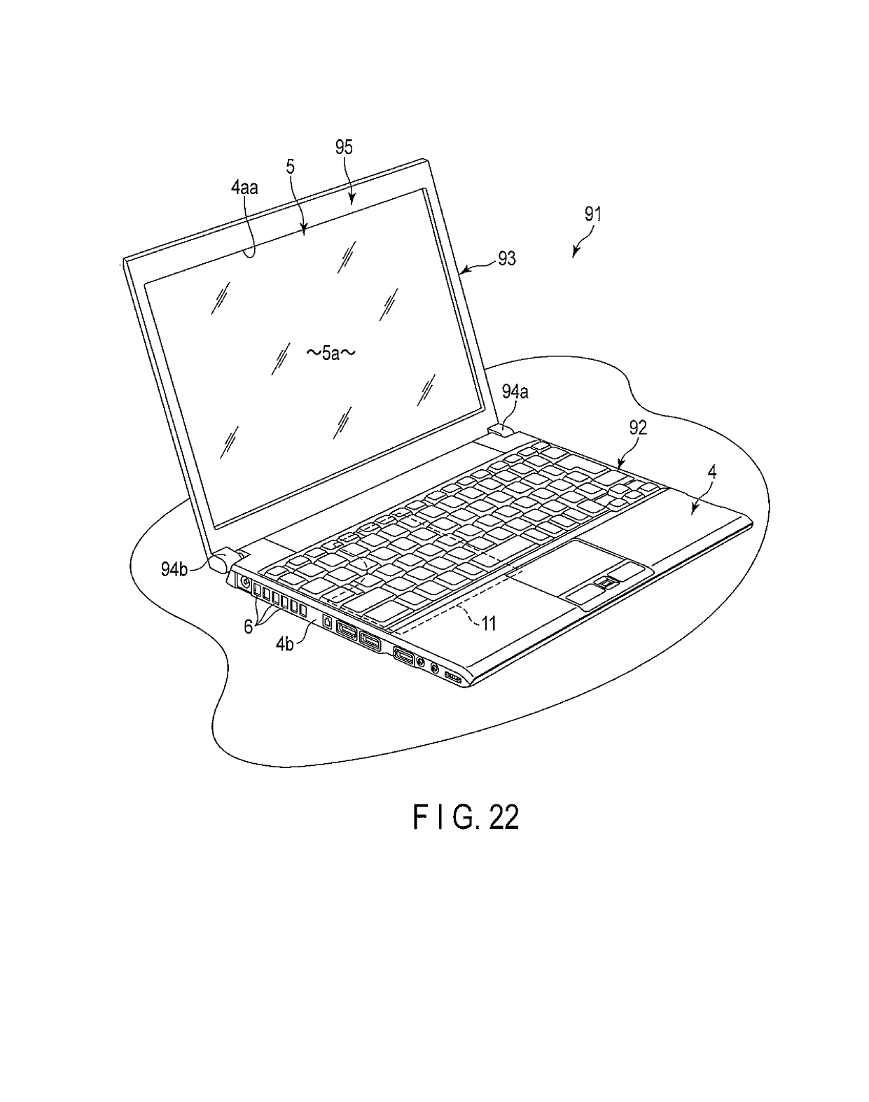

Next, an electronic apparatus 91 according to the twelfth embodiment will be described with reference to FIG. 22. Structures other than the following structures are the same as those in the first embodiment.

The electronic apparatus 91 is, for example, a notebook portable computer (i.e., notebook PC). As shown in FIG. 22, the electronic apparatus 91 includes a first unit 92, a second unit 93, and hinge portions 94a and 94b. The first unit 92 is, for example, an electronic apparatus main unit. The first unit 92 includes a first housing 4. The first housing 4 includes the circuit board 11, the first component 16, and the reinforcing portion 41 according to any one of the first to eleventh embodiments.

The second unit 93 is, for example, a display unit and includes a second housing 95 and a display device 5 provided in the second housing 95. The second housing 95 includes an opening portion 4aa through which a display screen 5a is exposed to the outside.

The second housing 95 is rotatably (i.e., openably) connected to the rear end portion of the first housing 4 by the hinge portions 94a and 94b. In this way, the electronic apparatus 91 can be rotated between a first position where the first unit 92 and the second unit 93 overlap each other and a second position where the first unit 92 and the second unit 93 are opened.

The embodiments are not limited to the above-described embodiments, but the components of the above-described embodiments may be changed without departing from the scope and spirit of the invention. In addition, a plurality of components according to the above-described embodiments may be appropriately combined with each other to form various embodiments. For example, some of the components according to the above-described embodiments may be removed. Components according to different embodiments may be appropriately combined with each other.

The first to twelfth embodiments can be widely applied to various kinds of electronic apparatuses including notebook PCs, televisions, mobile phones, smart phones, e-book terminals, and game machines.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a housing;
a display in the housing, the display comprising a display screen;
a circuit board electrically connected to the display and comprising a first surface and a second surface, the second surface opposite to the first surface;
a component comprising four corners, four sides, and a plurality of bumps inside an outer circumferential surface of the component, the plurality of bumps arranged in a lattice along the four sides and electrically connected to the first surface of the circuit board, the component configured to generate heat when the component is supplied power; and
four reinforcing portions on the second surface of the circuit board, each of the reinforcing portions corresponding to a corner of the four corners and comprising a first portion and a second portion, the first portion facing an outermost bump of the plurality of bumps, the second portion located outside the plurality of bumps.

2. The television of claim 1,
wherein the plurality of bumps comprise a first bump and second bumps in outermost positions among the plurality of bumps, the first bump located in a vicinity of a first corner of the four corners as an outermost bump, the second bumps located farther from the first corner than the first bump, and
a first reinforcing portion of the reinforcing portions faces the first bump and does not face at least one of the second bumps.

3. The television of claim 2,
wherein an edge of the first reinforcing portion is along the second bumps.

4. The television of claim 2,
wherein an edge of the first reinforcing portion is located between the first bump and the outer circumferential surface of the component.

5. The television of claim 1,
wherein the reinforcing portions are soldered to the circuit board.

6. The television of claim 1,
wherein each of the reinforcing portions has an L shape along the corresponding corner.

7. The television of claim 1,
wherein the circuit board comprises a second component between two of the reinforcing portions on the second surface.

8. The television of claim 1,
wherein the circuit board comprises a second component and a second reinforcing portion, the second component is between the component and an end of the circuit board on the first surface or the second surface, the second reinforcing portion is on a rear side of the second component and covers a circumference of the second component.

9. An electronic apparatus comprising:
a housing;
a circuit board in the housing, the circuit board comprising a first surface and a second surface, the second surface opposite to the first surface;
a component on the first surface of the circuit board, the component comprising a semiconductor mounting portion and a plurality of bonding portions, the semiconductor mounting portion comprising a corner, the plurality of bonding portions arranged in a lattice and comprising a first bonding portion and second bonding portions in outermost positions of the plurality of bonding portions, the second bonding portions being farther from the corner than the first bonding portion; and
a reinforcing portion on the second surface of the circuit board, wherein the reinforcing portion comprises a portion outside the first bonding portion with respect to a center of the semiconductor mounting portion, and the reinforcing portion does not cover at least one of the second bonding portions.

10. An electronic apparatus comprising:
a housing;
a circuit board in the housing, the circuit board comprising a first surface and a second surface, the second surface opposite to the first surface;
a component on the first surface of the circuit board, the component comprising a corner; and
a reinforcing portion on the second surface of the circuit board, the reinforcing portion corresponding to the corner of the component.
